(19) United States
(12) Patent Application Publication
(10) Pub. No.: US 2015/0200318 A1
(43) Pub. Date: Jul. 16, 2015

(54) COMBINATION SIGNAL MARKER PANEL AND SOLAR PANEL

(71) Applicant: LAURA THIEL, RALEIGH, NC (US)

(72) Inventor: LAURA THIEL, RALEIGH, NC (US)

(21) Appl. No.: 14/156,094

(22) Filed: Jan. 15, 2014

(51) Int. Cl. H01L 31/042

(52) U.S. Cl. CPC H01L 31/042

(57) ABSTRACT

A combination signal marker panel and solar panel and methods are disclosed. The combination signal marker panel and solar panel includes a signal marker that is sewed or otherwise fastened to a flexible solar panel. The solar panel is modular and configurable to provide any output voltage. Namely, the solar panel can include any number of solar modules configured in series, configured in parallel, or configured in any combination of series and parallel arrangements. The combination signal marker panel and solar panel can be used to harvest solar energy while simultaneously marking the user's position.

### TECHNICAL FIELD

The presently disclosed subject matter relates generally to portable equipment for aviation, military, personal survival, hiking, and camping applications and, more particularly, to a combination signal marker panel and solar panel.

### BACKGROUND

Certain distress signals are used in, for example, aviation applications, military applications, wilderness and personal survival applications, hiking and camping applications, and disaster relief efforts. One example of a distress signal is a signal marker panel (sometimes called a rescue marker panel). In military applications, the signal marker panel often is laid out on the ground to identify troop positions to friendly aircraft, or to identify where help is needed. In any of the aforementioned applications, signal marker panels can be used when search aircraft are in use. A signal marker panel typically is formed of a durable, lightweight, and foldable fabric that has a highly visible color, such as red, orange, yellow, or white.

In, for example, military applications or disaster relief efforts, separate signal marker panels and solar panels have been used independently of one another, although often at the same time and at the same location. Carrying multiple pieces of equipment, such as a separate marker panel and solar panel, means added weight and bulk, as well as multiple pieces of equipment to keep track of and maintain. Further, conventional substrates used in solar panels tend to be heavy and rigid, which does not lend well to portability.

### SUMMARY

In some aspects, the presently disclosed subject matter provides a portable distress signal comprising a signal marker panel and a solar panel assembly, wherein the solar panel assembly comprises one or more solar modules and is fastened to an edge of the signal marker panel, wherein the one or more solar modules are mounted to a flexible substrate and are electrically connected to one another and to one or more output connectors, and wherein the signal marker panel is configured to fold outward from the solar panel assembly to form a distress signal or to fold inward toward the solar panel assembly to protectively cover the one or more solar modules comprising the solar panel assembly.

In other aspects, the presently disclosed subject matter provides a method for deploying a portable distress signal, the method comprising: (a) providing a portable distress signal comprising a signal marker panel and a solar panel assembly, wherein the solar panel assembly comprises one or more solar modules and is fastened to an edge of the signal marker panel, wherein the one or more solar modules are mounted to a flexible substrate and are electrically connected to one another and to one or more output connectors, and wherein the signal marker panel is configured to fold outward from the solar panel assembly to form a distress signal or to fold inward toward the solar panel assembly to protectively cover the one or more solar modules comprising the solar panel assembly; (b) unfolding the signal marker panel from the solar panel assembly; and (c) arranging the signal marker panel to be visible to anyone in the vicinity thereof and/or arranging the solar panel assembly to harvest solar energy.

Certain aspects of the presently disclosed subject matter having been stated hereinabove, which are addressed in whole or in part by the presently disclosed subject matter, other aspects will become evident as the description proceeds when taken in connection with the accompanying Examples and Drawings as best described herein below.

### BRIEF DESCRIPTION OF THE DRAWINGS

Having thus described the presently disclosed subject matter in general terms, reference will now be made to the accompanying Drawings, which are not necessarily drawn to scale, and wherein:

FIG. 1 and FIG. 2 illustrate front and rear perspective views, respectively, of an example of the presently disclosed combination signal marker panel and solar panel that is lightweight, foldable, substantially waterproof, and well-suited for portability;

FIG. 3A, FIG. 3B, and FIG. 3C illustrate plan views of example configurations of the presently disclosed combination signal marker panel and solar panel;

FIG. 4 illustrates an exploded view of the solar panel of the presently disclosed combination signal marker panel and solar panel;

FIG. 5 illustrates a plan view of the substrate of the solar panel of the presently disclosed combination signal marker panel and solar panel;

FIG. 6A and FIG. 6B illustrate side views of a portion of the solar panel assembly, showing two example methods of electrically connecting the solar module to the substrate;

FIG. 7 illustrates a portion of the solar panel of the presently disclosed combination signal marker panel and solar panel, showing a hook and loop system for securing the edges of the fabric around the edges of the solar modules;

FIG. 8, FIG. 9, FIG. 10, and FIG. 11 show schematic views of examples of configuring the solar modules in the solar panel of the presently disclosed combination signal marker panel and solar panel;

FIG. 12, FIG. 13, FIG. 14, and FIG. 15 show a process of folding the presently disclosed combination signal marker panel and solar panel; and

FIG. 16 illustrates a flow diagram of an example of a method of deploying the presently disclosed combination signal marker panel and solar panel.

### DETAILED DESCRIPTION

The presently disclosed subject matter now will be described more fully hereinafter with reference to the accompanying Drawings, in which some, but not all embodiments of the presently disclosed subject matter are shown. Like numbers refer to like elements throughout. The presently disclosed subject matter may be embodied in many different forms and should not be construed as limited to the embodiments set forth herein; rather, these embodiments are provided so that this disclosure will satisfy applicable legal requirements. Indeed, many modifications and other embodiments of the presently disclosed subject matter set forth herein will come to mind to one skilled in the art to which the presently disclosed subject matter pertains having the benefit of the teachings presented in the foregoing descriptions and the associated Drawings. Therefore, it is to be understood that the presently disclosed subject matter is not to be limited to the specific embodiments disclosed and that modifications and other embodiments are intended to be included within the scope of the appended claims.

Conventional signal marker panels and solar panels typically are provided separately and used independently of one another. In contrast, the presently disclosed subject matter provides a combination signal marker panel and solar panel. Namely, in the combination signal marker panel and solar panel, one edge of a signal marker is sewed or otherwise fastened to one edge of a flexible solar panel. The presently disclosed combination signal marker panel and solar panel is lightweight, flexible (i.e., foldable or rollable), and substantially waterproof or at least water resistant. As a result, the combination signal marker panel and solar panel is well-suited for portability and for use in adverse conditions.

An aspect of the presently disclosed combination signal marker panel and solar panel is that both the signal marker panel and the solar panel fulfill their traditional functions unhindered. Namely, the signal marker panel and the solar panel can be used simultaneously, or the signal marker panel can be used alone, or the solar panel can be used alone.

Another aspect of the presently disclosed combination signal marker panel and solar panel is that the signal marker panel can be positioned to provide secondary protection to the solar panel, and solar modules thereof, when folded up and stowed.

Yet another aspect of the presently disclosed combination signal marker panel and solar panel is that the solar panel is modular and configurable to provide any output voltage. Namely, the solar panel can include any number of solar modules configured in series, configured in parallel, or configured in any combination of series and parallel arrangements.

Yet another aspect of the presently disclosed combination signal marker panel and solar panel is that the substrate of the solar panel is formed of a material, such as polyethylene, for example, a flashspun high-density polyethylene, e.g., DuPont™ Tyvek® material, which is lightweight, flexible (i.e., foldable or rollable), printable, and substantially waterproof or at least water resistant.

Yet another aspect of the presently disclosed combination signal marker panel and solar panel is the use of DuPont™ Tyvek® material as a substrate for electronics in a flexible panel (i.e., the flexible solar panel of the combination signal marker panel and solar panel). Namely, the electrical traces for electrically connecting any configuration of solar modules can be easily printed on the DuPont™ Tyvek® substrate using, for example, electrically conductive ink, while at the same time the DuPont™ Tyvek® substrate is flexible enough to be folded and stowed for storage.

Yet another aspect of the presently disclosed combination signal marker panel and solar panel is that because the substrate of the solar panel is printable, assembly instructions and/or any other markings can be printed thereon for assisting the assembly of the solar modules on the substrate.

Yet another aspect of the presently disclosed combination signal marker panel and solar panel is that the output voltage of the solar panel is provided in an unregulated state. As a result, the complexity of the solar panel is reduced as compared with conventional solar panels, because it does not include voltage conditioning circuitry at its output.

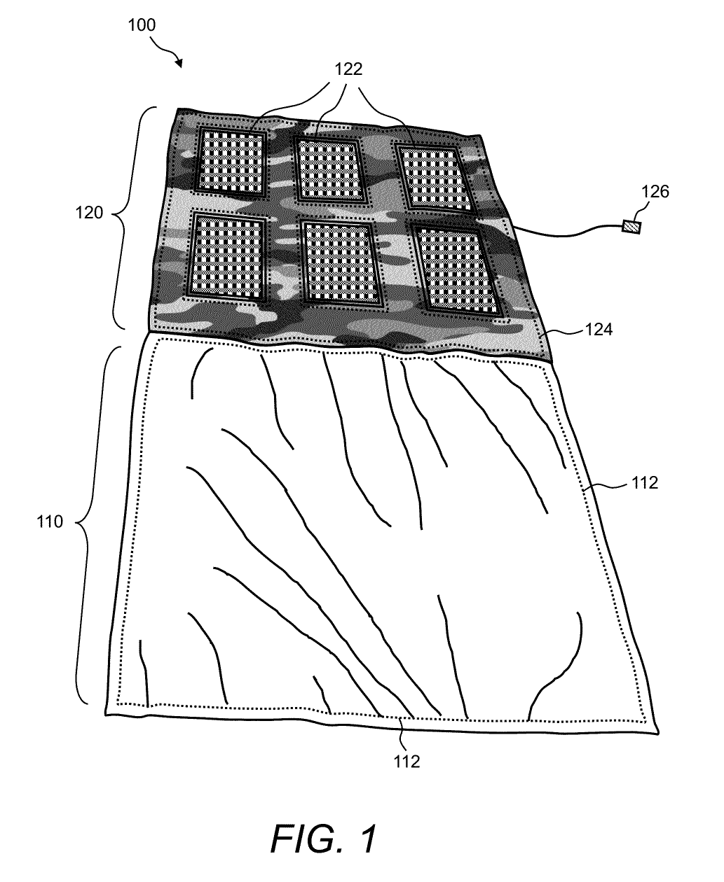

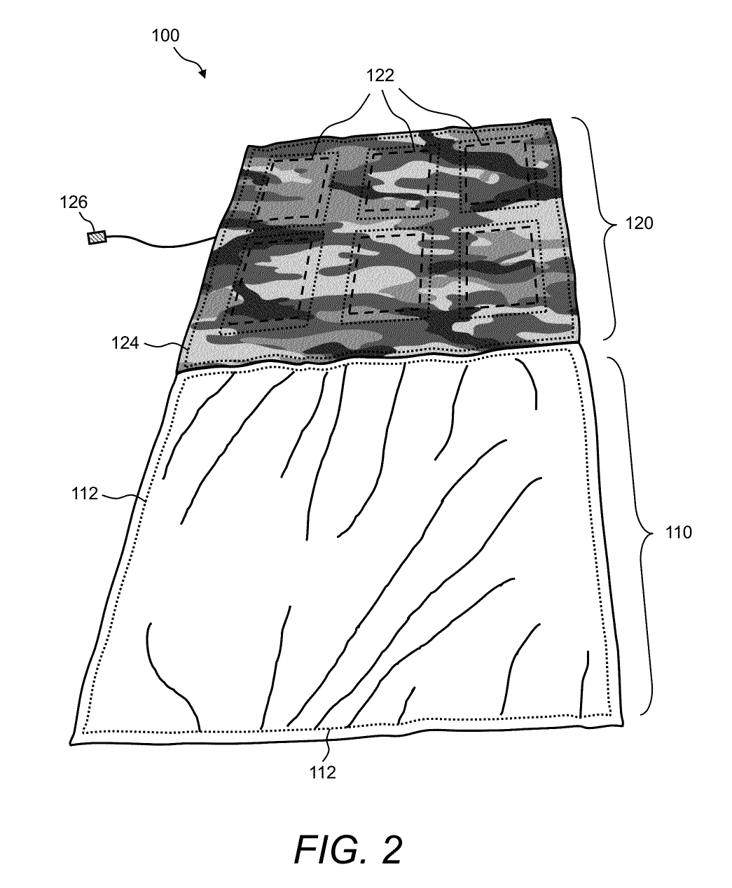

FIG. 1 and FIG. 2 illustrate front and rear perspective views, respectively, of an example of the presently disclosed combination signal marker panel and solar panel 100 that is lightweight, foldable, substantially waterproof or at least water resistant, and well-suited for portability. The combination signal marker panel and solar panel 100 includes a signal marker panel 110 and a solar panel 120 that are fastened together.

The signal marker panel 110 of the combination signal marker panel and solar panel 100 can be formed of any flexible, durable, and substantially waterproof or at least water resistant material used in conventional signal marker panels. For example, the signal marker panel 110 can be formed of polyester, polyvinyl chloride (PVC)-coated polyester, vinyl-coated polyester, nylon, canvas, PVC-coated canvas, or polycotton canvas. The signal marker panel 110 can be any color suitable for signaling, such as, but not limited to, red, orange, yellow, and white. A hem 112 may be provided around the perimeter of the signal marker panel 110.

The solar panel 120 of the combination signal marker panel and solar panel 100 is a multilayer structure that includes a plurality, e.g., one or more, of solar modules 122 mounted on a flexible substrate, wherein the flexible substrate with the plurality of solar modules 122 is sandwiched between two layers of substantially waterproof fabric. Openings, e.g., windows, are formed in at least one of the two layers of fabric for exposing the solar modules 122. The outer two layers of fabric can be any color or pattern. In the example shown in FIG. 1 and FIG. 2, the outer two layers of fabric have a camouflage pattern thereon. One of ordinary skill in the art would recognize that the two layers of fabric can have any camouflage pattern including, but not limited to, Universal camouflage pattern (UCP) or ACUPAT; UCP-Delta; Operation Enduring Freedom Camouflage Pattern (OCP) or MultiCam; Airman Battle Uniform (ABU); Navy Working Uniform (NWU); MARPAT (desert and woodlands); Disruptive Overwhite Snow digital camouflage; and Tactical Assault Camouflage or TACAM.

A hem 124 may be provided around the perimeter of the solar panel 120. The output of any arrangement of solar modules 122 in the solar panel 120 is a direct current (DC) voltage. Accordingly, the solar panel 120 includes an output connector 126 that is wired to the arrangement of solar modules 122. The output connector 126 is used for connecting any type of DC load to the solar panel 120. In one example, the solar panel 120 is used for supplying power a device, such as a DC-powered radio. In another example, the solar panel 120 is used for charging a battery.

The length and width of the signal marker panel 110 can be about the same or can be different. The footprint of signal marker panel 110 can be, for example, square or rectangular. The length and width of the signal marker panel 110 can be, for example, from about 8 inches to about 48 inches. In one example, the signal marker panel 110 is about 36×36 inches.

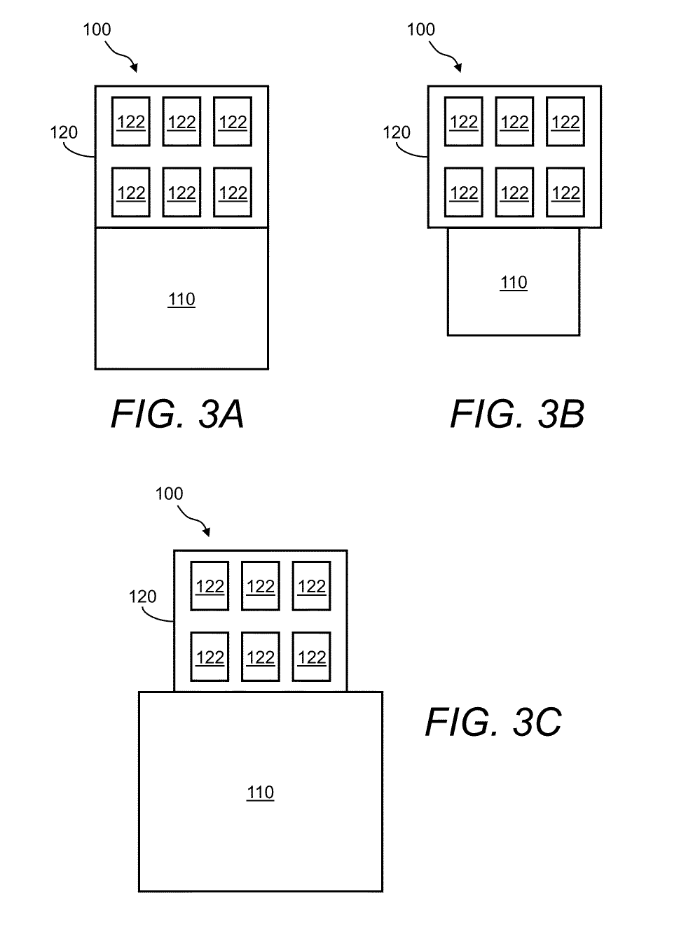

Similarly, the length and width of the solar panel 120 can be about the same or can be different. The footprint of solar panel 120 can be, for example, square or rectangular. The length and width of the solar panel 120 can be, for example, from about 8 inches to about 48 inches. In one example, the solar panel 120 is about 36×36 inches. The signal marker panel 110 and the solar panel 120 can be substantially the same size or can be different sizes and still be joined together. For example, FIG. 1, FIG. 2, and FIG. 3A show an example of the combination signal marker panel and solar panel 100 wherein the signal marker panel 110 and the solar panel 120 are substantially the same size. FIG. 3B, however, shows an example of the combination signal marker panel and solar panel 100 wherein a smaller signal marker panel 110 is joined to a larger solar panel 120. Further, FIG. 3C shows an example of the combination signal marker panel and solar panel 100 wherein a larger signal marker panel 110 is joined to a smaller solar panel 120.

In combination signal marker panel and solar panel 100, one edge of the signal marker panel 110 is sewed, adhered, or otherwise fastened to one edge of the solar panel 120 in a substantially permanent fashion. In another example, however, the signal marker panel 110 can be detachable from the solar panel 120. For example, one edge of the signal marker panel 110 can be fastened to one edge of the solar panel 120 using a zipper, an arrangement of buttons or snaps, or a hook-and-loop fastener system.

The hook-and-loop fastener system can comprise a first strip comprising hooks and a second strip comprising loops. The first strip and the second strip are adhered, e.g., glued, sewn, or otherwise attached, to opposing surfaces to be fastened. For example, in some embodiments, the first strip comprising hooks is attached to the signal marker panel 110 and the second strip comprising loops is attached to the solar panel 120. In other embodiments, the first strip comprising hooks is attached to the solar panel 120 and the second strip comprising loops is attached to the signal marker panel 110. When the first strip and the second strip are pressed together, the hooks catch in the loops and the two strips reversibly bind or fasten. The two strips can be separated by pulling apart.

The hook-and-loop fastener system can be made of any appropriate material known in the art including, but not limited to, nylon, polyester, Teflon®, and the like. Velcro® is an example of a hook-and-loop fabric fastener system.

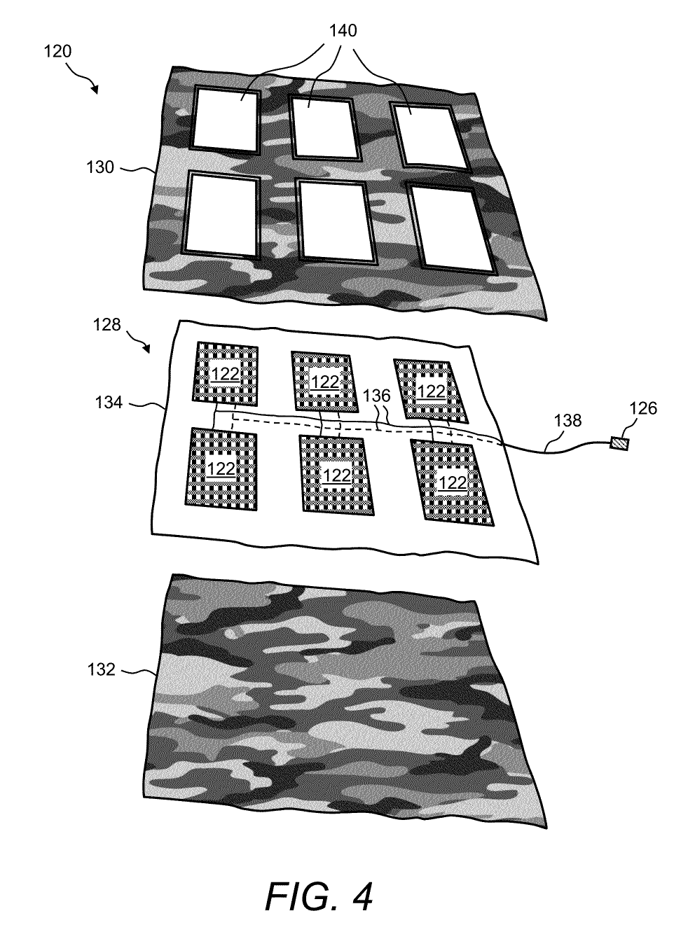

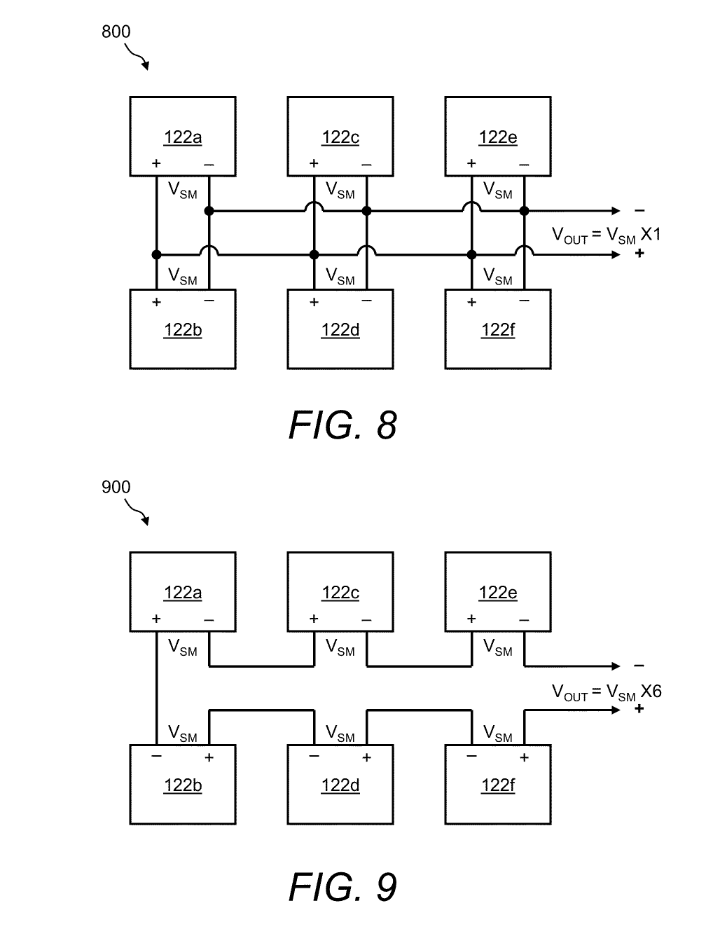

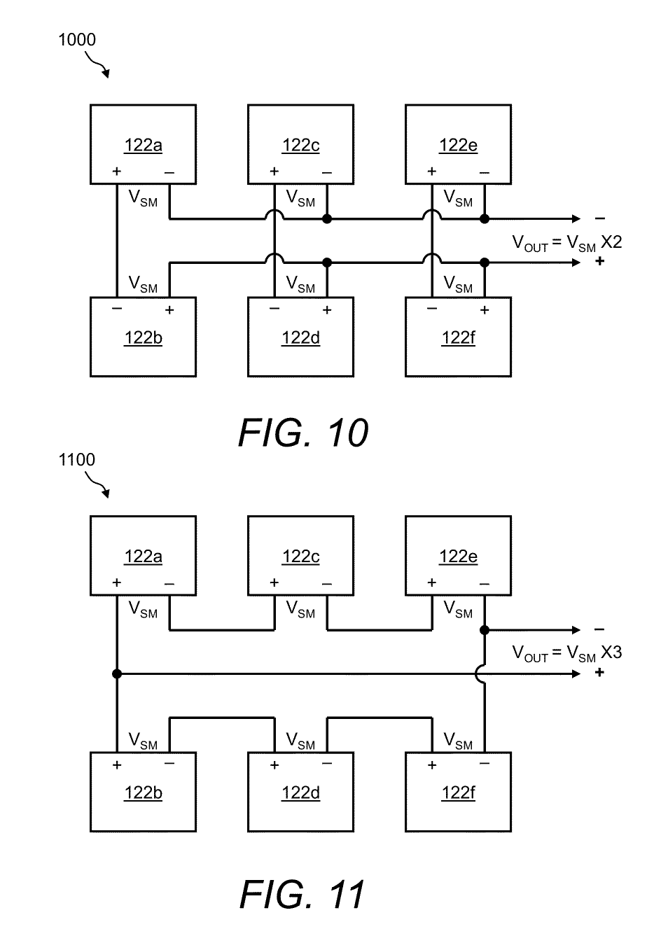

The solar panel 120 of the combination signal marker panel and solar panel 100 is modular and configurable to provide any output voltage. While FIG. 1 through FIG. 3C show six solar modules 122 in the solar panel 120, this is exemplary only. The solar panel 120 can include any number of solar modules 122 configured in series, configured in parallel, or configured in any combination of series and parallel arrangements. In particular, the configuration of solar modules 122 in the solar panel 120 can be tailored in any way to provide a certain output voltage and current. More details of the solar panel 120 of the combination signal marker panel and solar panel 100 are shown and described herein below with reference to FIG. 4 through FIG. 7. Additionally, example configurations of solar modules 122 are shown and described herein below with reference to FIG. 8, FIG. 9, FIG. 10, and FIG. 11.

FIG. 4 illustrates an exploded view of the solar panel 120 of the presently disclosed combination signal marker panel and solar panel 100, wherein the solar panel 120 comprises a multilayer structure. Namely, the solar panel 120 includes a solar panel assembly 128 that is sandwiched between a first fabric layer 130 and a second fabric layer 132.

The first fabric layer 130 and the second fabric layer 132 can be formed of any flexible, durable, and substantially waterproof or at least water resistant material, such as but not limited to, polyester, PVC-coated polyester, vinyl-coated polyester, nylon, canvas, PVC-coated canvas, and polycotton canvas. The first fabric layer 130 and the second fabric layer 132 can be any color or pattern, such as the camouflage pattern shown in FIG. 4. Additionally, the first fabric layer 130 and the second fabric layer 132 can be the same color or pattern or can be different colors or patterns.

The solar panel assembly 128 of the solar panel 120 includes the plurality of solar modules 122 mounted on a flexible substrate 134. Materials for forming the solar modules 122 include, but are not limited to, amorphous silicon, copper indium gallium (di)selenide (CIGS), and thin film crystals grown in outer space, such as the crystals used in solar cells of space stations, space shuttles, and satellites. The size of the solar modules 122 can be, for example, from about 1 inch to about 48 inches on a side. In one example, each solar module 122 is about 3 inches by about 6 inches.

A set of windows or openings 140 is provided in the first fabric layer 130 for exposing the faces of the solar modules 122. The sizes and positions of the windows or openings 140 in the first fabric layer 130 substantially correspond to the sizes and positions of the solar modules 122 on the flexible substrate 134.

The flexible substrate 134 is formed of a material that is lightweight, flexible (i.e., foldable or rollable), printable, and substantially waterproof or at least water resistant. In one example, the flexible substrate 134 is formed of DuPont™ Tyvek® material (available from DuPont, Wilmington, Del.). The solar modules 122 can be mounted on the flexible substrate 134 using, for example, an adhesive. When the solar panel 120 is assembled, the solar panel assembly 128 is substantially hidden from view between the first fabric layer 130 and the second fabric layer 132, except for the faces of the solar modules 122 showing through the windows or openings 140.

Wherein DuPont™ Tyvek® material is conventionally used as a vapor barrier material in weatherization systems in buildings, one aspect of the presently disclosed combination signal marker panel and solar panel 100 is the use of DuPont™ Tyvek® material as a substrate for electronics in a flexible panel (i.e., the solar panel 120). Namely, a pattern of wiring traces 136 for electrically connecting any configuration of solar modules 122 can be easily printed on the DuPont™ Tyvek® substrate using, for example, electrically conductive ink, while at the same time the DuPont™ Tyvek® substrate is flexible enough to be folded and provides a layer of water barrier to protect the solar modules 122.

One end of a cable or wire 138 is electrically connected to the wiring traces 136, while the connector 126 is on the opposite end of the cable or wire 138. The connector 126 can be any type or style of connector needed to mate to the equipment to be used with the combination signal marker panel and solar panel 100. The solar panel assembly 128 is not limited to one connector 126 or to one type or style of connector 126. A plurality of connectors 126 (or the same type or different types) can be connected to cable or wire 138. In this way, the combination signal marker panel and solar panel 100 can be used to supply multiple devices at the same time, albeit the multiple devices must have substantially the same power requirements. For example, by providing a plurality of connectors 126, the combination signal marker panel and solar panel 100 can be used to charge multiple batteries at the same time or to power multiple pieces of equipment at the same time.

In other embodiments, instead of printing wiring traces 136 on the flexible substrate 134, a discrete flexible wiring harness (not shown) is provided for electrically connecting the solar modules 122 and the connector 126. When the solar panel 120 is assembled, the wiring harness is substantially hidden from view between the first fabric layer 130 and the second fabric layer 132, except for the connector 126 extending outward from one edge.

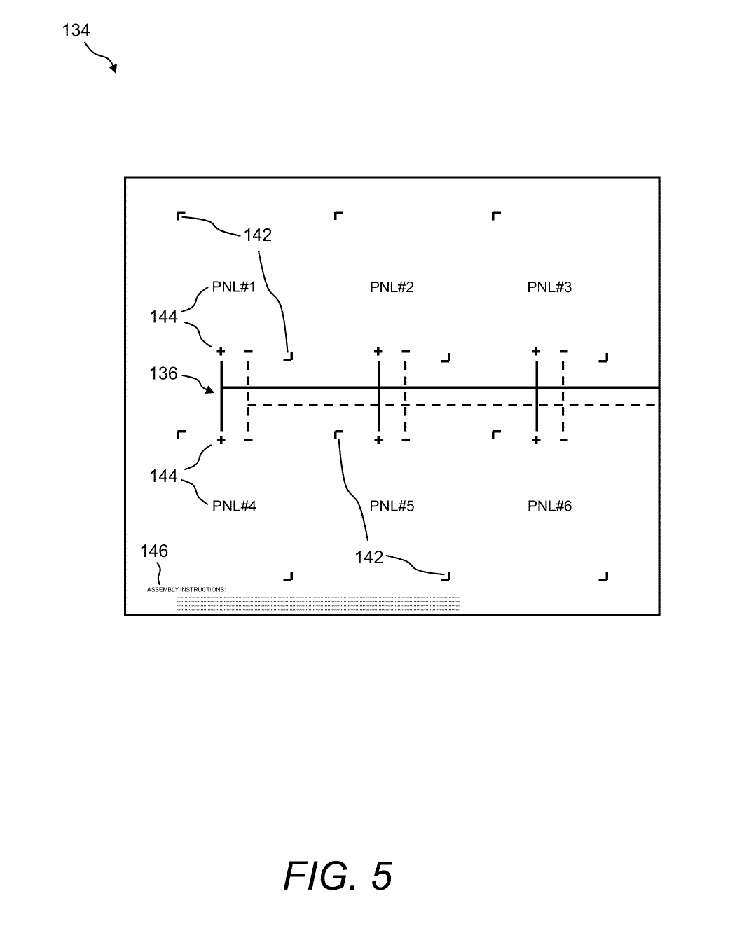

Because the flexible substrate 134 (e.g., the DuPont™ Tyvek® substrate) of the solar panel 120 is printable, assembly instructions and/or any other markings can be printed thereon for assisting the assembly of the solar modules on the substrate. For example, FIG. 5 illustrates a plan view of the flexible substrate 134 of the solar panel 120 of the presently disclosed combination signal marker panel and solar panel 100. In this example, FIG. 5 shows wiring traces 136 printed on the flexible substrate 134 using, for example, electrically conductive ink. FIG. 5, however, also shows a set of alignment features 142 that mark the corners of each of the solar modules 122. Additionally, each position of a solar module 122 may have certain text 144 printed thereon, such as PNL#1, PNL#2, PNL#3, PNL#4, PNL#5, and PNL#6, and polarity indicators (+ and −). Further, step-by-step assembly instructions 146 can be printed in any available space on the flexible substrate 134. The alignment features 142, the text 144, and the assembly instructions 146 can be printed using standard permanent ink. Standard printing processes can be used for both the electrically conductive ink and the permanent ink.

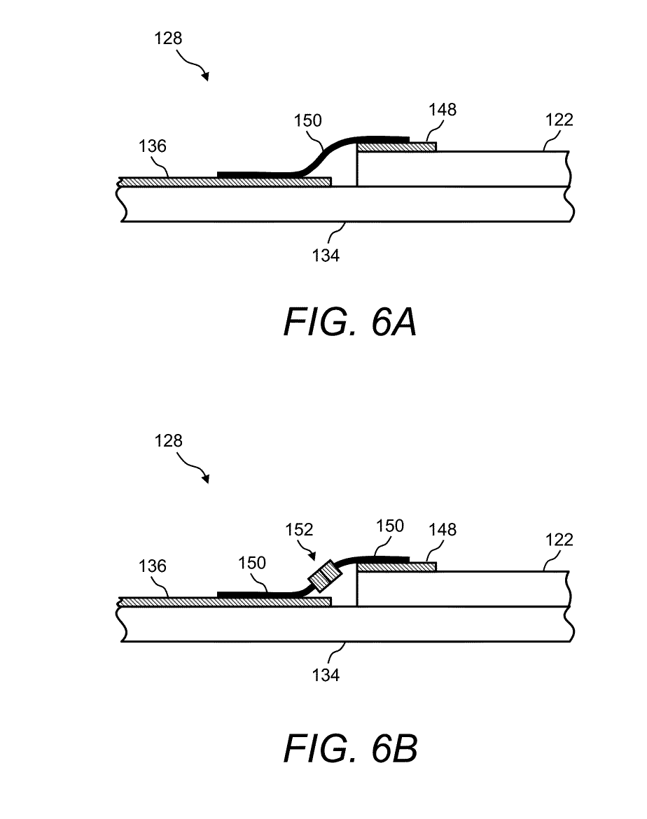

FIG. 6A and FIG. 6B illustrate side views of a portion of the solar panel 120 assembly, showing two example methods of electrically connecting the solar module 122 to the flexible substrate 134. In one example, FIG. 6A shows an output pad 148 of the solar module 122 in close proximity to a wiring trace 136 on the flexible substrate 134. A conductor 150, such as a flexible conductor, is used to electrically connect the output pad 148 of the solar module 122 to the wiring trace 136. For example, one end of the conductor 150 is soldered to the output pad 148 of the solar module 122 and the other end of the conductor 150 is soldered to the wiring trace 136. In this example, to replace the solar module 122, the conductor 150 is desoldered and removed, the solar module 122 is removed from the flexible substrate 134, a replacement solar module 122 is mounted on the flexible substrate 134, and the conductor 150 is soldered to the output pad 148 of the replacement solar module 122 and the wiring trace 136.

In another example, FIG. 6B shows a connector 152 installed along the length of the conductor 150. In this example, to replace the solar module 122, the connector 152 is disconnected, the solar module 122 is removed from the flexible substrate 134, a replacement solar module 122 is mounted on the flexible substrate 134, and the connector 152 is reconnected.

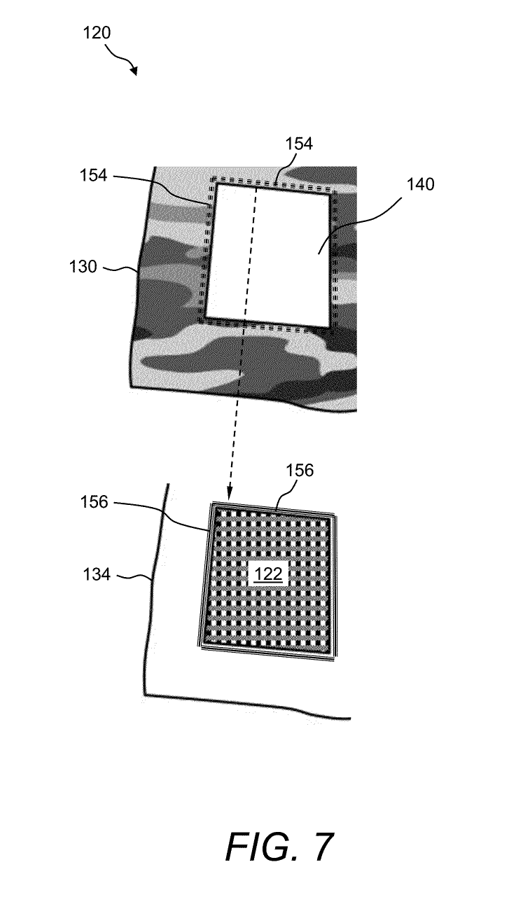

FIG. 7 illustrates a portion of the solar panel 120 of the presently disclosed combination signal marker panel and solar panel 100, showing a hook and loop system for securing the edges of the first fabric layer 130 around the edges of the solar modules 122. By way of example, FIG. 7 shows one window or opening 140 in the first fabric layer 130 and one solar module 122 of the solar panel assembly 128. An arrangement of hook strips 154 is provided on the first fabric layer 130 around the edges of the window or opening 140 and an opposing arrangement of loop strips 156 is provided on the flexible substrate 134 around the edges of solar module 122. In another embodiment, the loop strips 156 are on the first fabric layer 130 and the hook strips 154 are on the flexible substrate 134. The hook strips 154 and the loop strips 156 are, for example, components of a Velcro® hook-and-loop fastening system.

In yet another embodiment, instead of using a hook-and-loop fastening system, stitching is provided around the windows or openings 140, wherein the stitching passes through all of the layers of the solar panel 120 (i.e., through the first fabric layer 130, the flexible substrate 134, and the second fabric layer 132). In this example, however, it must be ensured that the stitching not interfere with any wiring traces 136 on the flexible substrate 134.

Referring now to FIG. 1 through FIG. 7, the combination signal marker panel and solar panel 100 can include other features. For example, the combination signal marker panel and solar panel 100 can include an elastic band or strap (not shown) that is used for wrapping around the combination signal marker panel and solar panel 100 when folded. Further, the combination signal marker panel and solar panel 100 can include an integrated pocket (not shown) for holding the signal marker panel 110 when the solar panel 120 is in use while the signal marker panel 110 is not in use. Additionally, the combination signal marker panel and solar panel 100 can include features that allow the combination signal marker panel and solar panel 100 to be wearable. For example, the combination signal marker panel and solar panel 100 can include features (not shown) that allow it to be worn on the users back (e.g., such as attached to a backpack), wherein the solar panel 120 portion of the combination signal marker panel and solar panel 100 can be unfurled and exposed to sunlight while the user is hiking Further, an additional connectors (not shown) can be provided that allows a plurality of solar panels 120 of multiple combination signal marker panel and solar panels 100 to be connected together in series or in parallel.

FIG. 8, FIG. 9, FIG. 10, and FIG. 11 show schematic views of examples of configuring the solar modules 122 in the solar panel 120 of the presently disclosed combination signal marker panel and solar panel 100. Again, FIG. 8, FIG. 9, FIG. 10, and FIG. 11 show six solar modules 122, but this is exemplary only. The solar panel 120 can include any number of solar modules 122.

Namely, FIG. 8, FIG. 9, FIG. 10, and FIG. 11 show a configuration 800, a configuration 900, a configuration 1000, and a configuration 1100, respectively, wherein each of the configurations includes six solar modules 122. Namely, the configurations 800, 900, 1000, and 1100 each include the solar modules 122a, 122b, 122c, 122d, 122e, and 122f. Additionally, each of the solar modules 122a, 122b, 122c, 122d, 122e, and 122f provides substantially the same output voltage (V_{SM}).

In the configuration 800, the solar modules 122a, 122b, 122c, 122d, 122e, and 122f are connected in parallel. Therefore, using the configuration 800, the output voltage (V_{OUT}) of the solar panel 120 is V_{SM}×1. In one example, if V_{SM}=3 volts, then V_{OUT} of the solar panel 120=3 volts.

In the configuration 900, the solar modules 122a, 122b, 122c, 122d, 122e, and 122f are connected in series. Therefore, using the configuration 900, the output voltage (V_{OUT}) of the solar panel 120 is V_{SM}×6. In one example, if V_{SM}=3 volts, then V_{OUT} of the solar panel 120=18 volts.

In the configuration 1000, the solar modules 122a and 122b are connected in series, the solar modules 122c and 122d are connected in series, and the solar modules 122e and 122f are connected in series. Therefore, each series-connected pair of solar modules 122 provides an output voltage of V_{SM}×2. Then, the three series-connected pairs of solar modules 122 are connected in parallel with each other. Namely, the series-connected pair of solar modules 122a and 122b, the series-connected pair of solar modules 122c and 122d, and the series-connected pair of solar modules 122e and 122f are connected in parallel with each other. Therefore, using the configuration 1000, the output voltage (V_{OUT}) of the solar panel 120 is V_{SM}×2. In one example, if V_{SM}=3 volts, then V_{OUT} of the solar panel 120=6 volts.

In the configuration 1100, the solar modules 122a, 122c, and 122e are connected in series and the solar modules 122b, 122d, and 122f are connected in series. Therefore, each series-connected arrangement of solar modules 122 provides an output voltage of V_{SM}×3. Then, the two series-connected arrangements of solar modules 122 are connected in parallel with each other. Namely, the series-connected arrangement of solar modules 122a, 122c, and 122e and the series-connected arrangement of solar modules 122b, 122d, and 122f are connected in parallel with each other. Therefore, using the configuration 1100, the output voltage (V_{OUT}) of the solar panel 120 is V_{SM}×3. In one example, if V_{SM}=3 volts, then V_{OUT} of the solar panel 120=9 volts.

In the event of failure of one or more solar modules 122 in the solar panel 120, one skilled in the art will recognize that parallel arrangements of the solar modules 122 provide certain advantages over series arrangements of the solar modules 122. For example, if one or more solar modules 122 fail in the configuration 800 of FIG. 8, the output voltage (V_{OUT}) of the solar panel 120 is not changed, albeit the current capacity is reduced. By contrast, if one solar module 122 fails in the configuration 900 of FIG. 9, the output voltage (V_{OUT}) of the solar panel 120 is reduced by an amount equal to the V_{SM} of the failing solar module 122.

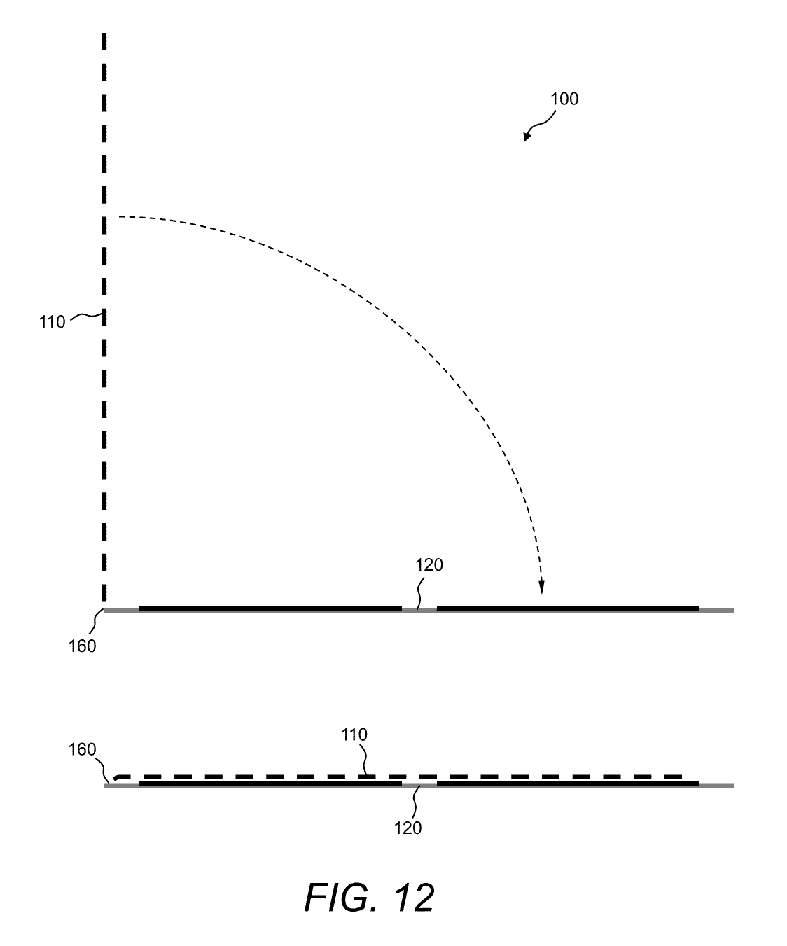

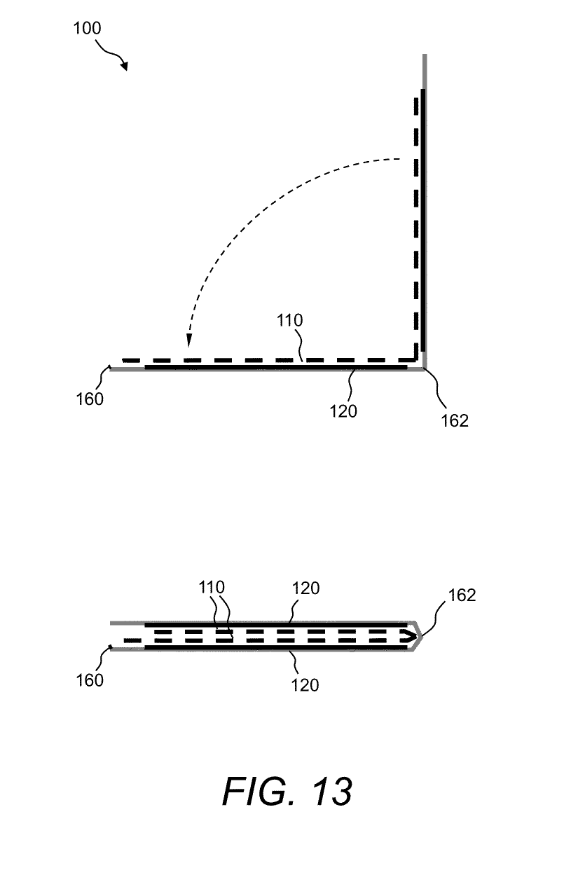

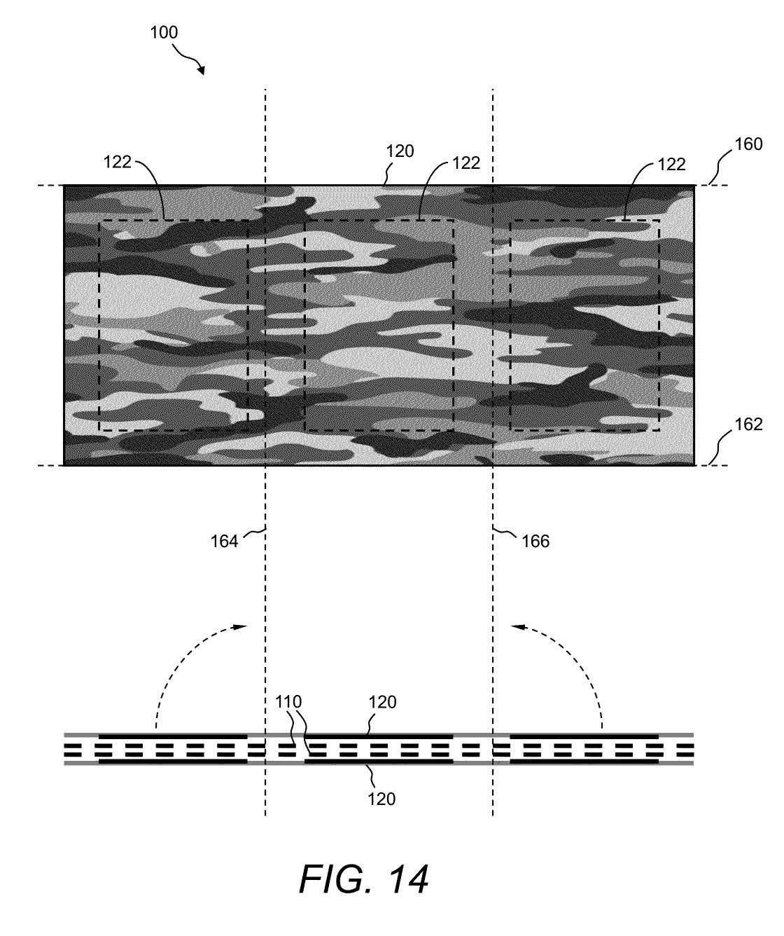

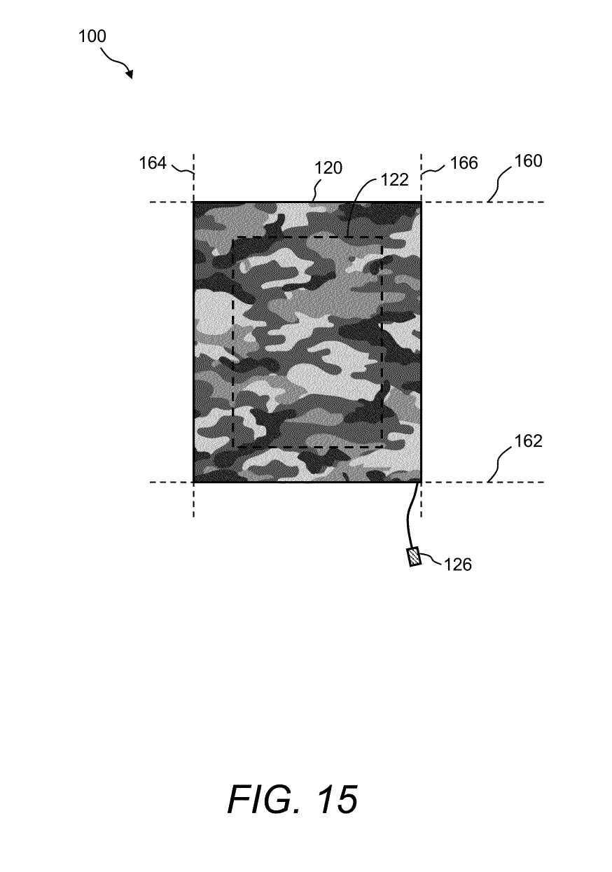

When configuring the solar modules 122 in the solar panel 120 of the combination signal marker panel and solar panel 100, another consideration of the size, number, and placement of the solar modules 122 on the flexible substrate 134 is the foldability of the combination signal marker panel and solar panel 100. Namely, providing enough space between solar modules 122 to allow the combination signal marker panel and solar panel 100 to be folded. Referring now to FIG. 12, FIG. 13, FIG. 14, and FIG. 15, an example of a process of folding the presently disclosed combination signal marker panel and solar panel 100 is presented. In this example, a process of folding the combination signal marker panel and solar panel 100 shown in FIG. 1 and FIG. 2 that includes six solar modules 122 is shown. This folding process, however, is exemplary only. The folding process depends on the configuration of solar modules 122 in the combination signal marker panel and solar panel 100 and can differ from one configuration to another.

In a first step and referring now to FIG. 12, the edge of the signal marker panel 110 that is farthest from the solar panel 120 is drawn across the solar panel 120 and toward the edge of the solar panel 120 that is farthest from the signal marker panel 110. In this way, a fold 160 is formed in the portion of the combination signal marker panel and solar panel 100 where the signal marker panel 110 and the solar panel 120 are joined together. By drawing the signal marker panel 110 over the surface of the solar panel 120, the signal marker panel 110 provides protection to the solar modules 122 when the combination signal marker panel and solar panel 100 is folded and stowed.

In a next step and referring now to FIG. 13, a fold 162 is formed at about the midway point of the solar panel 120, which is between two sets of solar modules 122.

In a next step and referring now to FIG. 14, a fold 164 and a fold 166 are formed such that the outer solar modules 122 are collapsed toward the inner solar modules 122. The result of the folding process is shown in FIG. 15, wherein the folded combination signal marker panel and solar panel 100 is about one sixth the size of the unfolded solar panel 120. Once folded, an elastic band or strap (not shown) can be wrapped around the folded combination signal marker panel and solar panel 100.

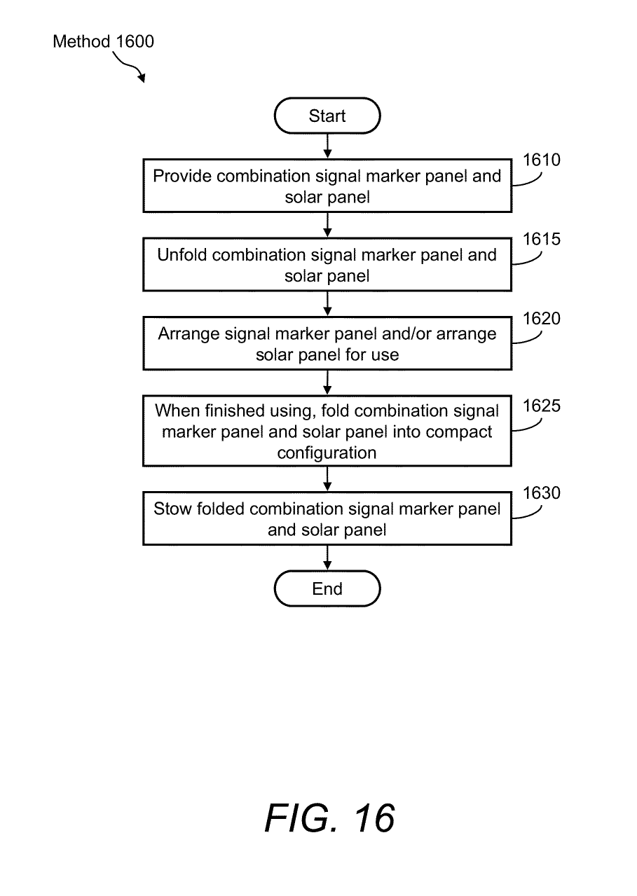

FIG. 16 illustrates a flow diagram of an example of a method 1600 of deploying the presently disclosed combination signal marker panel and solar panel 100. The method 1600 may include, but is not limited to, the following steps.

At a step 1610, the combination signal marker panel and solar panel 100 is provided.

At a step 1615, the user unfolds the combination signal marker panel and solar panel 100.

At a step 1620, the user arranges the signal marker panel 110 and/or the solar panel 120 of the combination signal marker panel and solar panel 100 for use. In one example, the signal marker panel 110 is laid out to be visible to anyone in the vicinity thereof while the position of the solar panel 120 is not important to the user. In another example, the solar panel 120 is laid out to harvest solar energy while the position of the signal marker panel 110 is not important to the user. Further, a pocket may be provided in the combination signal marker panel and solar panel 100 for holding the signal marker panel 110 when the solar panel 120 is in use. In yet another example, the signal marker panel 110 is laid out to be visible to anyone in the vicinity thereof and, at the same time, the solar panel 120 is laid out to harvest solar energy.

In still another example, the combination signal marker panel and solar panel 100 can include features that allow the combination signal marker panel and solar panel 100 to be wearable. For example, the combination signal marker panel and solar panel 100 can include features that allow it to be worn on the users back (e.g., such as attached to a backpack), wherein the solar panel 120 portion of the combination signal marker panel and solar panel 100 can be unfurled and exposed to sunlight while the user is hiking

At a step 1625, when the user is finished deploying the combination signal marker panel and solar panel 100, the user folds the combination signal marker panel and solar panel 100 into a compact configuration. In one example, the user folds the combination signal marker panel and solar panel 100 according to the example folding process shown in FIG. 12, FIG. 13, FIG. 14, and FIG. 15.

At a step 1630, the user stows the folded combination signal marker panel and solar panel 100. In one example, the user stows the folded combination signal marker panel and solar panel 100 in his/her backpack.

Referring now to FIG. 1 through FIG. 16, in one example application—a military application, the combination signal marker panel and solar panel 100 provides the following advantages over using separate signal marker panels and solar panels.
1) The combination signal marker panel and solar panel 100 can be used to harvest solar energy while simultaneously marking the user's position to friendlies in the battle space, both on the ground and in the air.
2) The combination signal marker panel and solar panel 100 has a small footprint that allows it to be draped over the user's backpack or rucksack, which allows the solar panel 120 portion to be used while on the move.
3) The small footprint of the combination signal marker panel and solar panel 100 facilitates stationary charging in tight spaces, and makes the overall folded or rolled dimension light enough and small enough to be carried by the user instead of the user carrying additional batteries.

Following long-standing patent law convention, the terms “a,” “an,” and “the” refer to “one or more” when used in this application, including the claims. Thus, for example, reference to “a subject” includes a plurality of subjects, unless the context clearly is to the contrary (e.g., a plurality of subjects), and so forth.

Throughout this specification and the claims, the terms “comprise,” “comprises,” and “comprising” are used in a non-exclusive sense, except where the context requires otherwise. Likewise, the term “include” and its grammatical variants are intended to be non-limiting, such that recitation of items in a list is not to the exclusion of other like items that can be substituted or added to the listed items.

For the purposes of this specification and appended claims, unless otherwise indicated, all numbers expressing amounts, sizes, dimensions, proportions, shapes, formulations, parameters, percentages, parameters, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some embodiments, ±100% in some embodiments ±50%, in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed methods or employ the disclosed compositions.

Further, the term “about” when used in connection with one or more numbers or numerical ranges, should be understood to refer to all such numbers, including all numbers in a range and modifies that range by extending the boundaries above and below the numerical values set forth. The recitation of numerical ranges by endpoints includes all numbers, e.g., whole integers, including fractions thereof, subsumed within that range (for example, the recitation of 1 to 5 includes 1, 2, 3, 4, and 5, as well as fractions thereof, e.g., 1.5, 2.25, 3.75, 4.1, and the like) and any range within that range.

Although the foregoing subject matter has been described in some detail by way of illustration and example for purposes of clarity of understanding, it will be understood by those skilled in the art that certain changes and modifications can be practiced within the scope of the appended claims.

That which is claimed:

1. A portable distress signal comprising:
a signal marker panel and a solar panel assembly, wherein the solar panel assembly comprises one or more solar modules and is fastened to an edge of the signal marker panel, wherein the one or more solar modules are mounted to a flexible substrate and are electrically connected to one another and to one or more output connectors, and wherein the signal marker panel is configured to fold outward from the solar panel assembly to form a distress signal or to fold inward toward the solar panel assembly to protectively cover the one or more solar modules comprising the solar panel assembly.

2. The portable distress signal of claim 1, wherein the solar panel assembly is permanently fastened to the signal marker panel.

3. The portable distress signal of claim 1, wherein the solar panel assembly is detachably fastened to the signal marker panel.

4. The portable distress signal of claim 3, wherein the solar panel assembly is detachably fastened to the signal marker panel by a fastening mechanism selected from the group consisting of a zipper, one or more buttons or snaps, a hook-and-loop system, and combinations thereof.

5. The portable distress signal of claim 1, wherein the solar panel assembly comprises one or more solar modules electrically connected to one another in a configuration selected from the group consisting of series, parallel, or combinations thereof.

6. The portable distress signal of claim 1, wherein the one or more solar panel modules are electrically connected by one or more electrical traces printed on the flexible substrate.

7. The portable distress signal of claim 1, wherein the substrate comprises polyethylene.

8. The portable distress signal of claim 7, wherein the polyethylene comprises a flashspun high-density polyethylene.

9. The portable distress signal of claim 1, wherein the signal marker panel comprises a material selected from the group consisting of a polyester, a polyvinyl chloride-coated polyester, a vinyl-coated polyester, nylon, canvas, polyvinyl chloride-coated canvas, and polycotton canvas.

10. The portable distress signal of claim 1, further comprising a first layer of fabric and a second layer of fabric positioned on a top and a bottom of the flexible substrate.

11. The portable distress signal of claim 10, wherein the first layer and second layer of fabric are substantially waterproof or water resistant.

12. The portable distress signal of claim 11, wherein the first layer and second layer of fabric each independently comprise a material selected from the group consisting of a polyester, a polyvinyl chloride-coated polyester, a vinyl-coated polyester, nylon, canvas, polyvinyl chloride-coated canvas, and polycotton canvas.

13. The portable distress signal of claim 10, wherein at least one of the first layer and the second layer of fabric comprises one or more openings, wherein the one or more openings have one or more dimensions substantially equivalent to one or more dimensions of the one or more solar modules.

14. The portable distress signal of claim 1, wherein the flexible substrate further comprises instructions printed thereon.

15. A method for deploying a portable distress signal, the method comprising:
(a) providing a portable distress signal comprising a signal marker panel and a solar panel assembly, wherein the solar panel assembly comprises one or more solar modules and is fastened to an edge of the signal marker panel, wherein the one or more solar modules are mounted to a flexible substrate and are electrically connected to one another and to one or more output connectors, and wherein the signal marker panel is configured to fold outward from the solar panel assembly to form a distress signal or to fold inward toward the solar panel assembly to protectively cover the one or more solar modules comprising the solar panel assembly;
(b) unfolding the signal marker panel from the solar panel assembly; and
(c) arranging the signal marker panel to be visible to anyone in the vicinity thereof and/or arranging the solar panel assembly to harvest solar energy.

16. The method of claim 15, further comprising folding the signal marker panel toward the solar panel assembly.

17. The method of claim 16, further comprising folding the solar panel assembly.

18. The method of claim 17, further comprising stowing the portable distress signal.

19. The method of claim 15, further comprising electrically connecting the one or more output connectors to one or more devices.

20. The method of claim 19, wherein the one or more devices are selected from the group consisting of a radio and a battery.
